(19) United States
(12) Patent Application Publication
(10) Pub. No.: US 2006/0174836 A1
(43) Pub. Date: Aug. 10, 2006

(54) Apparatus for heating wafer

(75) Inventors: Bang-weon Lee, Yongin-si (KR); Tae-gyu Kim, Hwaseong-si (KR); Jin-sung Lee, Seoul (KR); Dong-woo Lee, Seoul (KR); Tae-sang Park, Suwon-si (KR); Chang-hoon Jung, Seoul (KR); Sang-kwon Wee, Hwaseong-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/267,406

(22) Filed: Nov. 7, 2005

(30) Foreign Application Priority Data
Feb. 5, 2005 (KR) 10-2005-0010994

(51) Int. Cl. C23C 16/00; H05B 3/68

(52) U.S. Cl. 118/725; 219/444.1; 118/728

(57) ABSTRACT

An apparatus for heating a wafer includes a hot plate, formed of, for example, ceramic, which heats the wafer mounted thereon, a case supporting the hot plate, and a fixing unit fixing the hot plate to the case that is located under the hot plate. The fixing unit may include a ball for contacting and pressing the hot plate, and an elastic spring which presses the ball and which compresses when the hot plate expands thermally.

### BACKGROUND OF THE INVENTION

This application claims priority from Korean Patent Application No. 10-2005-0010994, filed on Feb. 5, 2005, in the Korean Intellectual Property Office, the disclosure of which is incorporated herein in its entirety by reference.

1. Field of the Invention

The present invention relates to an apparatus for manufacturing a semiconductor device and, more particularly, to an apparatus for heating a wafer.

2. Description of the Related Art

A heating process of uniformly heating a wafer at an appropriate temperature is often performed when manufacturing a semiconductor device. For example, a baking process is performed by coating a photoresist layer on a wafer and baking the wafer and the photoresist layer. During the baking process, the wafer is loaded on a hot plate of a wafer heating apparatus, such that the photoresist layer on the wafer is baked by the hot plate.

To this end, the hot plate including a heating wire for heating has a greater area than the wafer. The heating wire may be attached to a rear surface of the hot plate opposite to a front surface of the hot plate on which the wafer is loaded. Further, the hot plate may further include a cooling unit for keeping the temperature uniform.

The baking process requires a uniform temperature distribution. If the hot plate is thinner, the temperature can be more effectively controlled to be uniform. Accordingly, there have been many attempts to change the material of the hot plate and make the hot plate thinner. However, when the hot plate is thin, the hot plate may be damaged due to a thermal expansion coefficient difference when the hot plate is heated and/or cooled and thermally expands and/or contracts. Accordingly, a unit for fixing the hot plate to a case supporting the hot plate may have some problems.

For example, the hot plate is generally fixed to the case by a bolt. This conventional method using the bolt effectively prevents the hot plate from vibrating during the operation of a robot arm used for mounting and transferring the wafer. The conventional fixing method using the bolt comprises forming a through-hole in the hot plate and inserting the bolt into the through-hole such that the bolt engages with a groove formed in the case.

In the conventional fixing method using the bolt, due to a thermal expansion coefficient difference between the hot plate and the case, a severe stress concentration may occur at a portion where the bolt engages with the case when the hot plate thermally expands and/or contracts. Thus, the hot plate may be deformed or damaged at the portion where the bolt engages with the case due to the stress concentration.

Accordingly, to make the hot plate thinner so that the hot plate can heat the wafer at a uniform temperature, a technology to prevent damages to the hot plate due to a thermal expansion coefficient difference between the hot plate and the case is required.

### SUMMARY OF THE INVENTION

The present invention provides an apparatus for heating a wafer, which can employ a thin hot plate for heating the wafer and prevent the hot plate from being deformed or damaged due to a thermal expansion coefficient difference between the hot plate and a support case.

According to an aspect of the present invention, there is provided an apparatus for heating a wafer, comprising: a hot plate which heats a wafer mounted thereon; a case which supports the hot plate; and a fixing unit which fixes the hot plate to the case.

The hot plate may be formed of ceramic.

The fixing unit has one end coupled to the case and the other end which contacts and presses the hot plate without penetrating the hot plate such that the hot plate is fixed to the case.

The fixing unit may comprise: a body fixed to the case to be disposed on a side of the hot plate and having a hole directed toward the hot plate; a ball inserted into the hole formed in the body and contacting the hot plate; and an elastic spring that is inserted into the hole of the body to be disposed behind the ball, presses the ball so that the ball can press the hot plate, and is compressed when the hot plate expands thermally.

The hole of the body may be a through-hole, and the fixing unit may further include a fixing screw inserted into an inlet of the through-hole to fix the elastic spring to the body.

The hole of the body may have an inlet directed toward a side surface of the hot plate so that the ball contacts the side surface of the hot plate and presses the hot plate.

The side surface of the hot plate facing the hole of the body may be vertical, a side surface of the body facing the side surface of the hot plate and having the inlet of the hole formed therein may be parallel to the vertical surface of the hot plate, and the vertical surface of the hot plate may have a groove to receive the ball.

The side surface of the hot plate facing the hole of the body may be slanted, and a side surface of the body facing the slanted surface of the hot plate and having the inlet of the hole formed therein may be slanted so that the ball downwardly presses the slanted surface of the hot plate.

The hole of the body may have an inlet directed toward an upper edge portion of the hot plate so that the ball contacts the upper edge portion of the hot plate and presses the hot plate.

The hot plate may have a slanted surface, and the fixing unit may comprise: the body having a slanted surface facing the slanted surface of the hot plate; and a contact protrusion protruding from the slanted surface of the body and contacting the slanted surface of the hot plate.

A plurality of fixing units may be disposed at regular intervals on the case around the hot plate.

The apparatus may further comprise an auxiliary fixing unit that has one end coupled to the case and the other end contacting a top surface of an edge portion of the hot plate such that the hot plate is prevented from being separated from the case.

The apparatus may further comprise a support protrusion that is installed on a surface of the case facing a rear surface of the hot plate and contacts and supports the hot plate.

### BRIEF DESCRIPTION OF THE DRAWINGS

The above and other features and advantages of the present invention will become more apparent by describing in detail exemplary embodiments thereof with reference to the accompanying drawings, in which:

FIGS. 1 and 2 are respectively a cross-sectional view and a schematic view of an apparatus for heating a wafer according to an exemplary embodiment of the present invention;

FIG. 3 is a cross-sectional view of an apparatus for heating a wafer according to another exemplary embodiment of the present invention;

FIG. 4 is a cross-sectional view of an apparatus for heating a wafer according to still another aspect of the present invention;

FIG. 5 is a cross-sectional view of an apparatus for heating a wafer according to yet another exemplary embodiment of the present invention; and

FIG. 6 is a cross-sectional view of an apparatus for heating a wafer according to a further exemplary embodiment of the present invention.

### DETAILED DESCRIPTION OF EXEMPLARY EMBODIMENTS OF THE INVENTION

The present invention will now be described more fully with reference to the accompanying drawings, in which exemplary embodiments of the invention are shown. While the present invention has been particularly shown and described with reference to the exemplary embodiments, it will be understood by those of ordinary skill in the art that the present invention is not limited to the embodiments and various changes in form and details may be made therein without departing from the spirit and scope of the present invention as defined by the following claims.

In the exemplary embodiments of the present invention, a hot plate for a wafer heating apparatus is made of, for example, ceramic. A wafer is loaded on the hot plate and the hot plate uniformly heats the wafer, for example, in a baking process for baking a photoresist layer. Since the hot plate is made of ceramic, the hot plate may be manufactured to be thinner. For example, the hot plate may have a thickness of approximately 3 mm. Accordingly, the hot plate can more uniformly transfer heat produced by a hot wire, which may be attached to a rear surface of the hot plate, to the wafer mounted thereon. Accordingly, the process of baking the photoresist layer can be performed at a more uniform temperature.

Since the ceramic hot plate is thin, if a conventional fixing method in which a bolt passes through the hot plate to fix the hot plate to the case is used to fix the ceramic hot plate, the ceramic hot plate may suffer problems caused by a thermal expansion coefficient difference between the hot plate and the case. That is, a stress is concentrated on a portion where the bolt is coupled when the hot plate is heated and/or cooled and thermally expands and/or contracts, and thus a crack may occur at that portion.

To prevent such damage to the hot plate, the present invention uses a contact fixing method in which the fixing unit does not penetrate the hot plate instead of the conventional fixing method. Since an element, such as a bolt, which opposes the thermal expansion and/or contraction of the hot plate, is not used in the contact fixing method, problems such as a breakdown of the hot plate due to the bolt are prevented.

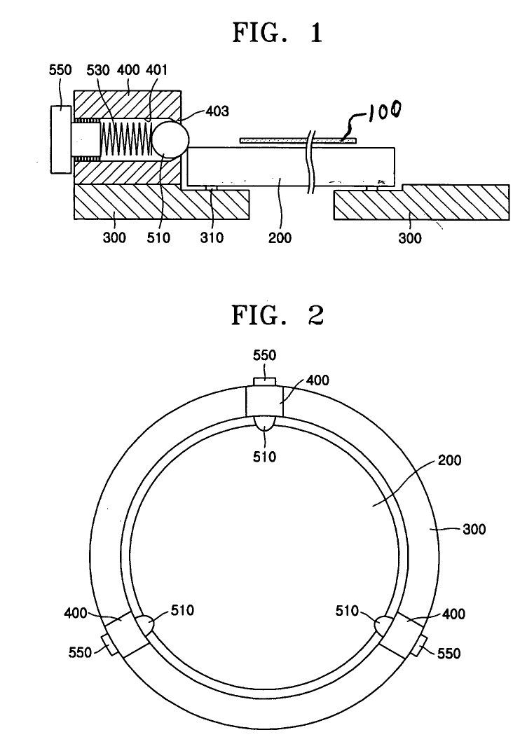

FIGS. 1 and 2 are respectively a cross-sectional view and a schematic view of an apparatus for heating a wafer according to an embodiment of the present invention.

Referring to FIG. 1, the wafer heating apparatus includes a ceramic hot plate 200 for heating a wafer 100 mounted thereon, a case 300 supporting the hot plate 200, and a fixing unit fixing the hot plate 200. The wafer 100 may have a front surface coated with a photoresist layer (not shown), and the wafer heating apparatus may be a photoresist baking apparatus.

To make the hot plate 200 thinner so that the wafer 100 can be controlled to have at a more uniform temperature distribution over the entire area, the hot plate 200 may be made of ceramic, for example, aluminia (Al₂O₃). The hot plate 200 made of ceramic can be thinner than a hot plate made of metal, and may have a thickness of approximately 3 mm or less. Since the hot plate 200 has such a small thickness, heat produced by a hot wire (not shown) disposed on a rear surface of the hot plate 200 can be more uniformly distributed and transferred to the wafer 100 mounted on the hot plate 200.

A support protrusion 310 may be formed on the case 300, which is disposed under the hot plate 300 and supports the hot plate 200. The support protrusion 310 may be disposed in the form of a pin to reduce a contact area between the hot plate 200 and the case 300 below the hot plate. Accordingly, heat loss of the hot plate 200 can be effectively reduced. Here, the support protrusion 310 supporting the hot plate 200 may not be coupled to the hot plate 200 to permit displacement of the hot plate 200 during expansion and/or contraction thereof.

A plurality of hot plates 200 may be arranged in parallel to one another so that the wafer heating apparatus can simultaneously heat a plurality of wafers 100. The wafer 100 is mounted on or removed from the hot plate 200 by operating a robot arm. The hot plate 200 may be unexpectedly separated from the case 300 due to vibrations caused during the operation of the robot arm. To prevent the unwanted separation of the hot plate 200, the fixing unit including a body 400 and a ball 510 is disposed around the hot plate 200 and fixes the hot plate 200 to the case 300. A plurality of fixing units including bodies 400 and balls 510 may be disposed at regular intervals as shown in FIG. 2.

Returning to FIG. 1, the fixing unit including the body 400 and the ball 510 is used in a contact fixing method. That is, instead of the conventional direct fixing method in which the hot plate 200 and the case 300 are directly coupled to each other using a bolt, the fixing unit including the body 400 and the ball 510 simply contacts the hot plate 200 and presses the hot plate 200 such that the hot plate 200 can be fixed to the case 300 in a contact manner.

The fixing unit including the body 400 and the ball 510 used in the contact fixing method may be configured in various ways. For example, as shown in FIG. 1, the fixing unit may include the body 400 disposed on a side of the hot plate 200 and fixed to the case, the ball 510 (preferably, but not necessarily, made of ceramic), an elastic spring 530, and a fixing screw 550 for fixing the spring 530. A through-hole 401 is formed in the body unit 400 and an inlet of the through-hole 401 is directed toward the hot plate 200.

Since the ceramic ball 510 is inserted into the through-hole 401 but a part of the ceramic ball 510 protrudes out of the inlet of the through-hole 401, the ceramic ball 510 can contact the adjacent hot plate 200. To enable the ceramic ball 510 to outwardly protrude while being inserted into the through-hole 401, a stepped portion 403 having a diameter less than the diameter of the inlet of the through-hole 401 may be formed at the inlet of the through-hole 401.

The elastic spring 530 may be disposed behind the ceramic ball 510 so that the ball 510 contacting the hot plate 200 can press the hot plate 200, and the fixing screw 550 may be disposed behind the elastic spring 530 to be screwed into the through-hole 401. The elastic spring 530 presses the ball 510 such that the ball 510 presses the hot plate 200. When the hot plate 200 expands thermally and the ball 510 is displaced, the elastic spring 530 is compressed to compensate for the thermal expansion of the hot plate 200. Although the ball 510 is displaced backwardly when the hot plate 200 expands thermally, the ball 510 returns to its original position where it can continuously press the hot plate 200 due to the elastic restoring force of the spring 530 when the hot plate 200 contracts. Accordingly, the ball 510 is in continuous contact with the hot plate 200 to fix and/or hold the hot plate 200 to the case 300.

The hole 401 formed in the body 400 of the fixing unit as shown in FIG. 1 may have an inlet directed toward an upper edge portion of the hot plate 200 so that the ball 510 can contact the upper edge portion of the hot plate 200 and press the hot plate 200. Then, the ball 510 comes in contact with the upper edge portion of the hot plate 200. As the ball 510 is disposed at the edge portion, a contact area between the ball 510 and the hot plate 200 is reduced, thereby more effectively reducing heat loss of the hot plate 200.

The ball 510 constituting the fixing unit may be disposed at other positions than the upper edge portion of the hot plate 200.

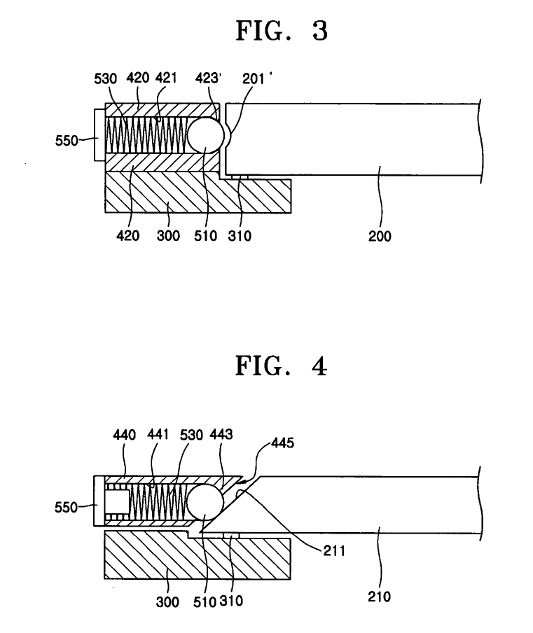

FIG. 3 is a cross-sectional view of an apparatus for heating a wafer according to another exemplary embodiment of the present invention.

Referring to FIG. 3, a hole 421 formed in a body 420 of a fixing unit may have an inlet directed toward a side surface of the hot plate 200 so that the ball 510 can contact the side surface of the hot plate 200 and press the hot plate 200. A stepped portion 423 may be formed at the inlet of the hole 421 to prevent the separation of the ball 510, and an elastic spring 530 may be disposed behind the ball 510.

Here, the side surface of the hot plate 200 facing the inlet of the hole 421 of the body 420 is vertical, and a side surface of the body 420 facing the side surface of the hot plate 200 is also vertical, parallel to the vertical surface of the hot plate 200. A groove 201 may be formed in the vertical surface of the hot plate 200 to receive the ball 510. The groove 201 receiving the ball 510 reinforces the force that fixes the hot plate 200.

In the meantime, to reinforce the force that fixes the hot plate 200 using the ball 510, the side surface of the hot plate 200 may have different shapes.

FIG. 4 is a cross-sectional view of an apparatus for heating a wafer according to still another exemplary embodiment of the present invention.

Referring to FIG. 4, a hole 441 formed in a body 440 of a fixing unit may have an inlet directed toward a side surface of a hot plate 210 so that the ball 510 can contact the side surface of the hot plate 220 and press the hot plate 210. A stepped portion 443 may be disposed at the inlet of the hole 441 to prevent the separation of the ball 510, and an elastic spring 530 may be disposed behind the ball 510.

The side surface of the hot plate 210 facing the inlet of the hole 421 of the body 440 may be an upwardly slanted surface 211. A side surface of the body 440 facing the slanted surface 211 of the hot plate 210 and having the inlet of the hole 441 formed therein may be slanted so that the ball 510 can downwardly press the slanted surface 211.

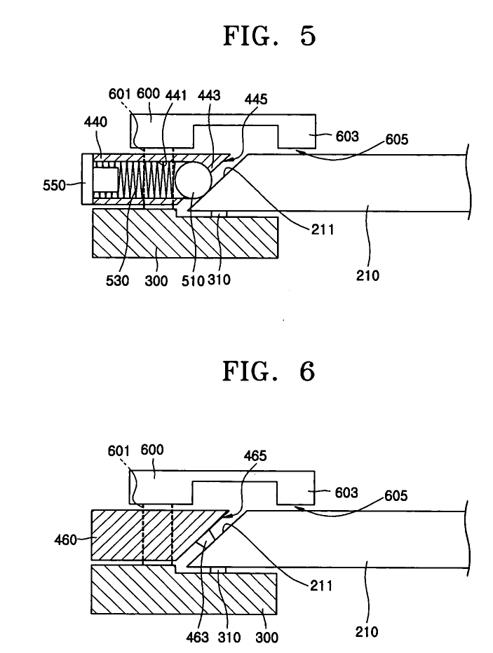

FIG. 5 is a cross-sectional view of an apparatus for heating a wafer according to yet another exemplary embodiment of the present invention.

Referring to FIGS. 4 and 5, to more surely prevent the separation of the hot plate 210, the wafer heating apparatus may further include an auxiliary fixing unit 600 in addition to the fixing unit. The auxiliary fixing unit 600 has one end coupled to the case 300 and the other end contacting a top surface of an edge portion of the hot plate 210 such that the hot plate 210 is prevented from being separated from the case 300.

The auxiliary fixing unit 600 may include a coupling unit 601 coupled to the case 300 and a contact unit 603 extending to the top surface of the edge portion of the hot plate 210. The auxiliary fixing unit 600 may be a kind of latch that is disposed over the hot plate 210 and prevents the hot plate 210 from being separated in an upward direction from the case 300. Here, the auxiliary fixing unit 600 may include a press protrusion 605. When the auxiliary fixing unit 600 includes the press protrusion 605, the auxiliary fixing unit 600 may directly contact the top surface of the hot plate 210. Here, the auxiliary fixing unit 600 may be installed at a position of the fixing unit including the body 440 and the ball 510, or a plurality of auxiliary fixing units 600 may be installed at predetermined intervals.

FIG. 6 is a cross-sectional view of an apparatus for heating a wafer according to a further exemplary embodiment of the present invention.

Referring to FIG. 6, a fixing unit includes a body 460 and a contact protrusion 463. The body 460 has a slanted side facing the slanted surface 211 of the hot plate 210 and one end coupled to the case 300. The contact protrusion 463 protrudes from the slanted surface of the body 460, contacts the slanted surface 211 of the hot plate 210, and presses the hot plate 210.

In this case, the wafer heating apparatus may further include the auxiliary fixing unit 600 as shown in FIG. 5, which includes the coupling unit 601 coupled to the case 300 and the contact unit 603 extending to the top surface of the edge portion of the hot plate 210.

As described above, crack, breakdown, or deformation of the hot plate due to a thermal expansion can be prevented, the ceramic hot plate can be effectively fixed to the case, and the wafer can be more uniformly heated. That is, stress concentration due to a thermal expansion coefficient difference between the ceramic hot plate and the case during a high temperature process can be effectively prevented.

Damage to the hot plate can be prevented by compensating for the displacement of the ceramic hot plate in vertical and radial directions during the high temperature process using the elastic spring. Since a contact area between the hot plate and the fixing unit can be effectively reduced, heat loss to the case or the side surface can be effectively prevented. Since a bolt is not used, the hot plate can be more easily installed. Also, a hole into which the bolt is inserted does not need to be formed in the hot plate. Accordingly, the hot plate can be manufactured to have a lower thickness.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An apparatus for heating a wafer, comprising:
a hot plate which heats a wafer mounted thereon;
a case which supports the hot plate; and
a fixing unit having one end coupled to the case and another end which contacts and presses the hot plate without penetrating the hot plate such that the hot plate is fixed to the case.

2. The apparatus of claim 1, wherein the fixing unit comprises:
a body fixed to the case to be disposed on a side of the hot plate and having a hole directed toward the hot plate;
a ball inserted into the hole formed in the body and contacting the hot plate; and
an elastic spring that is inserted into the hole of the body to be disposed behind the ball, presses the ball so that the ball can press the hot plate, and is compressed when the hot plate expands thermally.

3. The apparatus of claim 2, wherein the hole of the body is a through-hole, and the fixing unit further includes a fixing screw inserted into an inlet of the through-hole to fix the elastic spring to the body.

4. The apparatus of claim 2, wherein the hole of the body has an inlet directed toward a side surface of the hot plate so that the ball contacts the side surface of the hot plate and presses the hot plate.

5. The apparatus of claim 4, wherein the side surface of the hot plate facing the hole of the body is vertical, a side surface of the body facing the side surface of the hot plate and having the inlet of the hole formed therein is parallel to the vertical surface of the hot plate, and the vertical surface of the hot plate has a groove in which the ball is received.

6. The apparatus of claim 4, wherein the side surface of the hot plate facing the hole of the body is slanted, and a side surface of the body facing the slanted surface of the hot plate and having the inlet of the hole formed therein is slanted so that the ball downwardly presses the slanted surface of the hot plate.

7. The apparatus of claim 4, wherein the hole of the body has an inlet directed toward an upper edge portion of the hot plate so that the ball contacts the upper edge portion of the hot plate and presses the hot plate.

8. The apparatus of claim 1, wherein the hot plate has a slanted surface, and the fixing unit comprises:
the body having a slanted surface facing the slanted surface of the hot plate; and
a contact protrusion protruding from the slanted surface of the body and contacting the slanted surface of the hot plate.

9. The apparatus of claim 1, wherein a plurality of fixing units are disposed at regular intervals on the case around the hot plate.

10. The apparatus of claim 1, further comprising an auxiliary fixing unit that has one end coupled to the case and another end contacting a top surface of an edge portion of the hot plate such that the hot plate is prevented from being separated from the case.

11. The apparatus of claim 1, further comprising a support protrusion that is installed on a surface of the case facing a rear surface of the hot plate and contacts and supports the hot plate.

12. An apparatus for heating a wafer, comprising:
a hot plate which heats a wafer mounted thereon;
a case which supports the hot plate; and
a hot plate fixing unit including:
a body fixed to the case to be disposed on a side of the hot plate and having a hole directed toward the hot plate;
a ball inserted into the hole formed in the body and contacting the hot plate;
an elastic spring that is inserted into the hole of the body to be disposed behind the ball, presses the ball so that the ball can press the hot plate, and is compressed when the hot plate expands thermally; and
a fixing member which fixes the elastic spring to the body.

13. The apparatus of claim 12, wherein the hole of the body has an inlet directed toward a side surface of the hot plate so that the ball contacts the side surface of the hot plate and presses the hot plate.

14. The apparatus of claim 13, wherein the side surface of the hot plate facing the hole of the body is vertical, a side surface of the body facing the side surface of the hot plate and having the inlet of the hole formed therein is parallel to the vertical surface of the hot plate, and the vertical surface of the hot plate has a groove in which the ball is received.

15. The apparatus of claim 13, wherein the side surface of the hot plate facing the hole of the body is slanted, and a side surface of the body facing the slanted surface of the hot plate and having the inlet of the hole formed therein is slanted so that the ball downwardly presses the slanted surface of the hot plate.

16. The apparatus of claim 13, wherein the hole of the body has an inlet directed toward an upper edge portion of the hot plate so that the ball contacts the upper edge portion of the hot plate and presses the hot plate.

17. The apparatus of claim 12, wherein the ball of the fixing unit is made of ceramic.

18. The apparatus of claim 12, further comprising an auxiliary fixing unit that has one end coupled to the case and another end contacting a top surface of an edge portion of the hot plate such that the hot plate is prevented from being separated from the case.

19. The apparatus of claim 12, further comprising a support protrusion that is installed on a surface of the case facing a rear surface of the hot plate and contacts and supports the hot plate.

20. An apparatus for heating a wafer, comprising:
a hot plate having a slanted side surface and which heats a wafer mounted thereon;
a case which supports the hot plate; and
a fixing unit including:
a body having a slanted side surface facing the slanted surface of the hot plate, and one end coupled to the case; and
a contact protrusion protruding from the slanted surface of the body and contacting and pressing the slanted surface of the hot plate such that the hot plate is fixed to the case.

21. The apparatus of claim 1, wherein the hot plate is made of ceramic.

22. The apparatus of claim 12, wherein the hot plate is made of ceramic.

23. The apparatus of claim 20, wherein the hot plate is made of ceramic.

24. The apparatus of claim 12, wherein the fixing member comprises a fixing screw.

25. The apparatus of claim 1, wherein the case is located under the hot plate.
